(19) United States
(12) Patent Application Publication
(10) Pub. No.: US 2007/0139231 A1
(43) Pub. Date: Jun. 21, 2007

(54) Systems and methods for enterprise-wide data identification, sharing and management in a commercial context

(75) Inventors: J. J. Wallia, Silver Spring, MD (US); Raphael Bousquet, Silver Spring, MD (US)

Correspondence Address: MILES & STOCKBRIDGE PC, 1751 PINNACLE DRIVE, SUITE 500, MCLEAN, VA, 22102-3833, US

(73) Assignee: Advanced Digital Forensic Solutions, Inc., Silver Spring, MD (US)

(21) Appl. No.: 11/651,546

(22) Filed: Jan. 10, 2007

Related U.S. Application Data
(63) Continuation-in-part of application No. 11/318,084, filed on Dec. 23, 2005.
(63) Continuation-in-part of application No. 11/318,340, filed on Dec. 23, 2005.
(60) Provisional application No. 60/757,708, filed on Jan. 10, 2006.
(60) Provisional application No. 60/728,208, filed on Oct. 19, 2005.
(60) Provisional application No. 60/728,208, filed on Oct. 19, 2005.

(51) Int. Cl. H03M 7/00

(52) U.S. Cl. 341/50

(57) ABSTRACT

Systems and methods for digital liability management, digital rights management and extrusion detection. The system includes identification components that identify particular data transiting a network.

### CROSS-REFERENCE TO RELATED APPLICATIONS

This application claims the benefit of U.S. Provisional Application No. 60/757,708, entitled “Systems and Methods for Enterprise-Wide Forensic Data Identification, Sharing and Management In a Commercial Context,” filed Jan. 10, 2006, which is hereby incorporated by reference. This application is also a continuation-in-part of U.S. patent application Ser. Nos. 11/318,084 and 11/318,340, filed Dec. 23, 2005, each of which is hereby incorporated by reference as if set forth fully herein, and each of which claims the benefit of U.S. Provisional Application No. 60/728,208, filed Oct. 19, 2005.

### BACKGROUND

1. Field

The present invention relates generally to data management and, more specifically, to systems and methods of digital data identification, storage, management, and processing of digital information.

2. Introduction

In corporate and private institution environments, present software applications fall short of automatically identifying potentially dangerous data on networks and employee computers. With email usage volumes growing, monitoring unauthorized exchange of proprietary data to prevent Intellectual Property (IP) theft is becoming increasingly difficult. Corporations need to prevent storage of unauthorized or unlicensed files which could lead to substantial financial losses from lawsuits from content providers. Several corporations ban employees from storing or exchanging non-company related data, as lawsuits from exchange of unauthorized data (e.g. pornography) have increased. Automatically identifying these files can save corporations both time and money.

For commercial organizations, the invention addresses application for Digital Liability Management (DLM); Digital Rights Management (DRM); and Extrusion Management.

Digital Liability as used herein refers to the ways the information on computer devices and networks can actually hurt a company or an individual. Even if all risks are “known,” managing the digital information that can cause liability is very difficult.

A company's digital assets can also create liability exposure. Some sources of digital liability exposure include: use of networked computers, e-commerce, websites, electronic records, automated transactions, digital signatures, and electronic contracting.

Activities that cause digital liability include: evidence of unlawful civil or criminal activity, illegal possession of unlicensed content, theft of trade secrets and other privileged information, theft of customer or partner information, disclosure of confidential information, and disclosure of trade secrets and other valuable information (designs, formulas etc.).

An organization must know which of its assets require protection and the real and perceived threats against them. Seventy percent (70%) of all computer attacks enter via the Internet, but 75% of all dollar losses stem from internal intrusions.

Corporations also need to control and limit liabilities from unforeseen lawsuits. Many corporations ban employees from storing or exchanging non-company related data to avoid lawsuits resulting from exchange of unauthorized data (e.g. pornography).

Corporations also need to take adequate steps to control and limit liabilities from employees using company resources to participate in criminal acts, e.g., exchange of child exploitation images, facilitating or participating in theft ID or counterfeiting activities, and, most importantly, participating in illegal covert activities.

Damage Estimations: A 2001 study by the Computer Security Institute and the FBI indicated that cybercrimes accounted for losses of $378 million. This was twice what the loss was in 2000. The majority of the losses came from theft of trade secrets, financial fraud, and damage from computer viruses. In 2002, a total of 223 respondents totaled $455 million in losses. Leaders were loss of proprietary info and financial fraud.

Other sources of digital liability risk include:
Excessive sharing: people often want to forward a sexually explicit joke found on the net. There is a potential liability with significant implications. An individual's civil rights can be violated, or the communication may be misinterpreted as harassment or offensive.
Digital records and communication are at the center of legal issues or used as supporting evidence.
For businesses, any email message sent by anyone with a company account may be used as evidence of company misconduct and become ammunition against a company, even if that message would have been disregarded by anyone with common sense and maturity at the company.

Thus, there is a need for a technology platform and solution to scan and manage digital data to enforce digital liability protection.

Several corporations and many federal, state, and local governmental organizations do not allow employees to store or exchange pornography on company or government owned computers. There have been several cases of random audits which have uncovered large amounts of stored pornography, leading to several complications for many parties involved.

Thus, there is a need for a technology platform and solution to scan and identify pornographic digital content to enforce digital liability protection.

Digital rights management (DRM) is an umbrella term referring to any of several technical methods used to handle the description, layering, analysis, valuation, trading and monitoring of the rights held over a digital work. In the widest possible sense, the term refers to any such management. For digital content providers and content owners, DRM technologies are necessary to prevent revenue loss due to illegal duplication of their copyrighted works. The digital rights management (DRM) industry is relatively young, emerging over the past fifteen years. In its initial stages, the DRM industry modeled itself along the lines of the prevalent rights management business models in the non-digital world. However, the emergence of digital technology made it possible to create perfect copies of on-line content. Later, the development of the Internet facilitated the dissemination of this content. Hence most of the DRM technologies developed during the late eighties and early nineties concentrated on copy protection. These are referred to as first generation DRM systems. Subsequently, those in the DRM industry became explicit in recognizing that DRM is in fact much more than copy protection alone.

The advent of digital rights management (DRM) has lead to the creation of two generations of DRM technologies. First generation technologies largely focused on copy protection, and because of this, many erroneously equate copy protection and DRM. Second generation technologies, however, have begun to address a much broader scope of possibilities associated with the myriad of business opportunities that can be built around the more general idea of managing rights.

In the DRM industry, the first phase appears to be the development of rudimentary DRM solutions which relied solely on copy protection. These solutions were content-provider-centric and were promptly rejected by the users because they failed to address their needs. The rise of second generation DRM systems can be seen as the transition to the second phase of the DRM market lifecycle. In particular, DRM vendors are busy developing customized end-to-end solutions for users. In the third phase, vendors are able to provide stable solutions, and they can successfully embed their technologies into business solutions which can address the needs of generic customers. In this phase, stable solutions are expected to evolve which address the “tussle” between the vendors and the customers, and a de facto agreement is reached between them.

In particular, DRM solution vendors are incentivized to provide solutions that will maximize the usage and visibility of their technologies, while users demand a transparent experience that does not necessarily favor particular vendors. Thus, successful solutions can involve a compromise that addresses the needs of the customer on one hand, and are profitable to the vendor on the other. The third phase also allows the vendors to market their products competitively.

In the third phase of the market, the tussle between the customer and vendor should achieve equilibrium. The solutions should be profitable to the vendor and simultaneously provide enough benefits to the customers. Only when such equilibrium is reached can the product survive in the market. If a DRM product overly favors one of the parties, then it will be rejected by the other.

Significant hurdles in developing stable DRM solutions are trust and security. No matter how user-centric a DRM solution is, its success will eventually depend upon the ability to enforce rights. That is, DRM is largely dependent on security solutions. There is however a major difference between security and rights enforcement. Rights enforcement is much difficult to achieve as it is concerned with controlling the usage of the content after delivering it to the user. This gives rise to trust.

Since most DRM vendors provide complete DRM solutions, customers are locked into specific DRM vendors. What customers demand is independence of DRM vendors. The customer should be able to switch the DRM vendors with minimal overload. In this sense, DRM presently has a reputation of getting in the way of using content.

Thus, there is a need for a technology platform that allows a balanced exchange of DRM rights and enforcement between content providers and users. Specifically, there is a need for a system that can manage content usage and inform both providers and users of any potential storage or usage of unlicensed content. Such solution platforms should allow the users to authenticate that the violation is accurate and also identify the potential source of the violation. The users should then have the option to rectify the situation prior to the content provider enforcing action.

Extrusion as used herein refers to the unauthorized transfer of a company's essential digital assets such as, for example, credit cards, customer records, transactional information, source code and other classified information.

The most important asset of many companies is their Intellectual Property (IP). Customer lists, customer credit card lists, copyrights including computer code, confidential product designs, proprietary information such as new products in formation, and trade secrets are all forms of IP that can be used against the company by its competitors. A laid-off employee is a prime source of potential leakage of such information.

Thus, many employees are restricted in their access to sensitive data, but Information Technology (IT) employees have access to sensitive data and processes. Indeed, IT employees are the custodians and authors of those objects. This may place them in positions to reveal information to others that will damage the company or directly sabotage a company's operations in various ways. When laid off, IT employees who are disgruntled, angry, or seeking to steal information for profitable gain, may attempt to steal sensitive digital information which could lead to substantial losses for the organization.

Information security builds layers of firewalls and content security at the network perimeter, and permissions and identity management that control access by trusted insiders to digital assets, such as business transactions, data warehouse and files. This structure lulls the business managers into a false sense of security.

Content-security tools based on HTTP/SMTP proxies are used against viruses and spam. However, these tools weren't designed for extrusion prevention. They don't inspect internal traffic; they scan only authorized e-mail channels. They rely on file-specific content recognition and have scalability and maintenance issues. When content security tools don't fit, they are ineffective. Relying on permissions and identity management is like running a retail store that screens you coming in but doesn't put magnetic tags on the clothes to prevent you from wearing that expensive hat going out.

Thus, there is a need for a solution to allow corporations to prevent unauthorized exchange of proprietary data. With email usage volumes growing, monitoring exchange of this data to prevent extrusion is becoming increasingly difficult.

For law enforcement and intelligence organizations, an increasing number of criminal and terrorist acts and preparations leading to such acts are leaving behind evidence in digital formats sometimes referred to as a “digital fingerprint.” The field of collecting and analyzing these types of data is called digital data identification. These digital formats vary widely and include typical computer files, digital videos, e-mail, instant messages, phone records, and so on. They are routinely gathered from seized hard drives, “crawled” Internet data, mobile digital devices, digital cameras, and numerous other digital sources that are growing steadily in sophistication and capacity. When accurately and timely identified by law enforcement agencies, digital evidence can provide the invaluable proof that clinches a case.

The FBI has indicated that digital evidence has spread from a few types of investigations, such as hacking and child pornography, to virtually every investigative classification, including fraud, extortion, homicide, identity theft, and so on.

The amount of evidence that exists in digital form is growing rapidly. This growth is demonstrated by the following information which was presented by the Federal Bureau of Investigation at the 14th INTERPOL Forensic Science Symposium: The Computer Analysis Response Team (CART) is the FBI's computer forensic unit and is primarily responsible for conducting forensic examinations of all types of digital hardware and media. According to FBI CART, the number of FBI cases has tripled from 1999 to 2003. This is the result of the increased presence of digital devices at crime scenes combined with a heightened awareness of digital evidence by investigators.

While the number of cases increased threefold from 1999 to 2003, the volume of data increased by forty-six times during the same period. Given the declining prices of digital storage media and the corresponding increases in sales of storage devices, the volume of digital information that investigators must deal with is likely to continue its meteoric increase.

This tremendous increase in data presents a number of problems for law enforcement. Traditionally, law enforcement has seized all storage media, created a drive image or duplicated it, and then conducted their examination of the data on the drive image or duplicated copy to preserve the original evidence. A “drive image” is an exact replica of the contents of a storage device, such as a hard disk, stored on a second storage device, such as a network server or even another hard disk. One of the first steps in the examination process is to recover latent data such as deleted files, hidden data and fragments from unallocated file space. This process is called data recovery and requires processing every byte of any given piece of media. If this methodology continues, the number of pieces of digital media with their increasing size will push budgets, processing capability and physical storage space to their limits. Compounding these problems are the practices of providing the defendant with a copy of the data and retaining the data for the length of the defendant's sentence.

The delay in identifying suspect data occasionally results in the dismissal of some criminal cases where the evidence is not being produced in time for prosecution.

Present solutions are efficient for data recovery, but still require manual review from examiners to identify specific data needed to prove guilt or innocence. None of the solutions today provide technologies or methodologies for identifying conclusive digital evidence automatically. Conclusive digital evidence is any digital evidence that can automatically either prove guilt (e.g., images of known child pornography), or indicate probable guilt (e.g., images of currency plates, driver's licenses, or terrorist training camps) that require authentication and/or further review to determine criminal activity. In an effort to reduce the volume of digital files for review, seized digital evidence is processed to reduce the amount of this data. These processes are called “data reduction” by forensic examiners.

A method currently used for data reduction involves performing a hash analysis against digital evidence. A cryptographic one-way hash (or “hash” for short) is essentially a digital fingerprint: a very large number that uniquely identifies the content of a digital file. A hash is uniquely determined by the contents of a file. Therefore, two files with different name but the exact same contents will produce the same hash.

The National Institute of Standards and Technology (NIST) produces a set of hash sets called the National Software Reference Library that contains hashes for approximately 7 million files as of 2004 (www.nsrl.nist.gov).

Files in a hash set typically fall into one of two categories. Known files are known to be “OK” and can typically be ignored, such as system files such as win.exe, explore.exe, etc. Suspect files are suspicious files that are flagged for further scrutiny; files that have been identified as illegal or inappropriate, such as hacking tools, encryption tools and so on.

A hash analysis automates the process of distinguishing between files that can be ignored while identifying the files known to be of possible evidentiary value. Once the known files have been identified then these files can be filtered. Filtering out the known files may reduce the number of files the investigator must evaluate.

Using hash systems to identify conclusive or known suspect files face several challenges. They cannot be used to identify multimedia files (image, video, and sound) that have been altered, whether minimally or substantially. As a consequence individuals using these files to commit crimes escape prosecution.

In addition, some law enforcement and intelligence agencies maintain disparate digital fingerprint hash sets, but no such agency currently has a system to create, catalog, and maintain its suspect data files. Although agencies are aware of the known suspect data or files, they do not have a comprehensive management system to catalog and maintain these data.

Digital forensic analysis tools used today are standalone systems that are not coordinated with systems used by the agency analysts and Information Technology (IT) staff. Agencies do not share information at an optimal level. This has become increasingly important since the terrorist attacks of Sep. 11, 2001, which created a strong demand for greater information sharing between law enforcement agencies. A primary reason this has not been achieved is that there are security risks associated with sharing classified data.

It would be beneficial and desirable to integrate newer, advanced hash technologies to automate the detection and classification process for suspect files and identify altered files. This would allow law enforcement to focus on identifying conclusive data during the forensic process and addresses many of the problems facing digital forensic examinations today. It would also be desirable to enable agencies to manage and share key suspect files and to use a common language to define an investigative strategy and data search. Furthermore, it would also be desirable to deploy advanced hash technologies to automatically identify dangerous files for corporations.

### SUMMARY

Embodiments of the present invention can comprise systems and methods for digital data identification for use in, for example, extrusion management, digital rights management, digital liability management, and digital forensics. Embodiments can additionally include the storage, management, and processing of digital data as potential evidence in computer systems. Various embodiments can provide Digital Liability Management (DLM); Digital Rights Management (DRM); and Extrusion Management for commercial organizations.

Various embodiments can comprise a component, which can be implemented as a software component, for conducting digital forensic searches. According to various embodiments, the component can include a header, one or more search markup language programs, and a data features section containing features of data. Furthermore, the component, also referred herein as a search pack, can be configured to enable a first entity, such as a federal investigation agency, or a company, to share its suspect and sensitive data with a second entity, such as another investigative agency or a second company, in a manner that allows the second entity to utilize the suspect data while not revealing the actual content of the sensitive data to the second agency. Thus, the second agency can perform comparisons and other operations on the sensitive data without having to know the actual content of the data. Therefore, embodiments can allow an investigative agency to define an investigative strategy for a particular case via the search markup language programs and by the data features that it includes in the search pack. By sharing search packs among agencies, an agency can share or inform others of that agency's theory of the case and investigative goal. Search packs can also be updated automatically as new information is learned about a particular case. However, how the search pack is updated can be determined by the agency that created it and manages it.

According to various embodiments, a search pack can contain a data verification section that includes some form of actual data representations of the sensitive data, such as thumbnail images or series of images in case of video, whereby a second entity, for example, can verify identification of potential suspect data that have been previously identified. In such embodiments, the features data in the search pack cannot be directly modified by any party other than the party that created the search pack.

Various embodiments can comprise a method of automatically identifying relevant or suspect data during a digital forensic investigation. Such various embodiments can accept as input raw data which are extracted from various digital data sources ranging from PCs to cell phones and the Internet. Such various embodiments can also comprise a digital forensic and data identification application configured to determine to which one or more identification modules the unknown raw data should be delivered to for processing. This determination can be based the type of data in the extracted raw data coming into the application. For example, if there are images in the incoming data then an image data identification module is invoked. Suspect or relevant data that are identified includes that data that are identical to or similar to the extracted unknown raw data. If there are suspect data, the application can transmit a message or alert to interested parties or store the findings/report on an a storage device. In this manner, the suspect data are identified automatically, without intervention by a human being.

In various embodiments, the identification modules are invoked in a search markup language interpreter and the one or more identification modules are expressed in a search markup language specifically for digital forensics and receive parameters from the search language for processing.

In particular, various embodiments can comprise an extrusion detection system having one or more analysis modules and a traffic rule engine, in which the traffic rule engine is coupled to the plurality of analysis modules and comprises preset rules, and in which the traffic rule engine is configured to select, based on said preset rules, an incoming data packet for extrusion analysis by at least one of the analysis modules, and in which each analysis module is configured to extract information from the incoming data packet in accordance with one of a plurality of protocols. The system can further comprise an identification module including one or more identification components comprising a header, a search markup language program, and a data features section containing features of data, in which the identification components are configured to identify suspect data and to allow sharing of said suspect data among a first entity and at least a second entity in a manner that enables utilization of the suspect data by the second entity while not revealing the actual content of sensitive data to the second entity; and in which the identification module is configured to output a report based on the suspect data.

The suspect data can be conclusive data. Further, in various embodiments, the features of data cannot be directly modified by the second entity.

Various embodiments can also comprise an extrusion detection method, comprising intercepting network traffic including digital data received from a local computer; rerouting the intercepted network traffic to a traffic rule engine; inspecting the rerouted traffic using preset rules to determine a part of the rerouted traffic to be analyzed; extracting, using a particular protocol, the determined part of the rerouted traffic to be analyzed from the network traffic and reconstructing the outgoing message; identifying suspect files transiting on the network by comparing the extracted traffic with one or more search packs to determine if a suspect file is transiting on the network, in which the one or more search packs comprise a header, a search markup language program, and an asset data features section; and outputting an activity report.

Further, various embodiments can comprise a digital liability management and brand protection method comprising intercepting internal network traffic and outgoing network traffic; rerouting the intercepted network traffic to a traffic rule engine; inspecting the rerouted traffic using preset rules to determine a part of the rerouted traffic to be analyzed; extracting, using a particular protocol, the determined part of the rerouted traffic to be analyzed from the network traffic and reconstructing the outgoing message; identifying suspect files transiting on the network by comparing the extracted traffic with one or more search packs to determine if a suspect file is transiting on the network, wherein said one or more search packs comprise a header, a search markup language program, and a protected asset data features section; and outputting a report including a global map showing the locations of protected assets.

Furthermore, in such embodiments, the header can contain internal company contact information. Also, the particular protocol can be a communication protocol such as, for example, SMTP, SIP, NFS, Samba, FTP, HTTP, Jabber, and Gnutella.

Furthermore, the preset rules can restrict the analysis to data coming from a local area network or going to a specific destination.

Further, in various embodiments, one or more of the search packs can identify protected assets.

Various embodiments can also comprise a digital liability and brand protection management system including one or more analysis modules, a traffic rule engine, in which the traffic rule engine is coupled to the analysis modules and comprises preset rules, the traffic rule engine being configured to select, based on said preset rules, an incoming data packet for liability analysis by at least one of the analysis modules; in which each analysis module is configured to extract information from the incoming data packet in accordance with one of a plurality of protocols; and an identification module including one or more identification components comprising a header, a search markup language program, and a protected asset data features section, in which the identification components are configured to identify suspect data and to allow sharing of said suspect data among a first entity and at least a second entity in a manner that enables utilization of the suspect data by the second entity while not revealing the actual content of sensitive data to the second entity; and in which the identification module is configured to output a report including a global map showing the locations of protected assets.

In such embodiments, the suspect data can be protected assets data.

Furthermore, in such embodiments, the features of data cannot be directly modified by the second entity. Also, in such embodiments, the one or more identification components can identify protected assets.

### BRIEF DESCRIPTION OF THE DRAWINGS

The invention may be more fully understood with reference to the accompanying drawing figures and the descriptions thereof. Modifications that would be recognized by those skilled in the art are considered a part of the present invention and within the scope of the appended claims.

FIG. 1 is a block diagram showing the relationships among data sources, applications, and a platform in accordance with various embodiments;

FIG. 2A is a block diagram showing in further detail digital forensic and data identification application 102 and its inputs and outputs in accordance with various embodiments;

FIG. 2B is a flow diagram showing an automatic data identification process in accordance with various embodiments;

FIG. 3 is a block diagram showing components of a search pack in accordance with various embodiments;

FIG. 4 is a block diagram showing in further detail a digital forensic and data identification platform and its inputs and outputs in accordance with various embodiments;

FIG. 5 is a block diagram of an extrusion detection system according to various embodiments;

FIG. 6 is a flow chart of an extrusion detection method according to at least one embodiment;

FIG. 7 is a digital liability and brand protection management system in accordance with at least one embodiment;

FIG. 8 is a flow chart of a digital liability and brand protection management method according to at least one embodiment; and

FIG. 9 is an extrusion detection report example of an activity report according to various embodiments.

### DETAILED DESCRIPTION

Embodiments can comprise systems and methods for digital data identification for use in, for example, extrusion management, digital rights management, digital liability management, and digital forensics. Embodiments can additionally include the storage, management, and processing of digital data as potential evidence in computer systems. These and other features of the present invention will become more fully apparent from the following description and appended claims, or may be learned by the practice of the invention as set forth herein. Various embodiments of the invention are discussed in detail below. While specific implementations are discussed, it should be understood that this is done for illustration purposes only. A person skilled in the relevant art will recognize that other components and configurations may be used without departing from the spirit and scope of the invention.

Various embodiments can comprise a system that includes a platform and an application which are further described, for example, in U.S. patent application Ser. No. 11/318,084, entitled “Methods for Searching Forensic Data,” and U.S. patent application Ser. No. 11/318,340, entitled “Systems and Methods for Enterprise-Wide Identification Data Sharing and Management,” both of which are by the inventors of the present application, are commonly-assigned to the assignee of the present application, and were filed Dec. 23, 2005, each of which is hereby incorporated by reference as if set forth fully herein.

Various embodiments can comprise tools for searching and performing other operations on forensic data, referred to as search packs and search markup language, SML. These inventions operate within digital forensic and data identification applications and platforms. Before Describing the concept and implementation details of search packs and SML, it is helpful to describe the application and platform in which they operate.

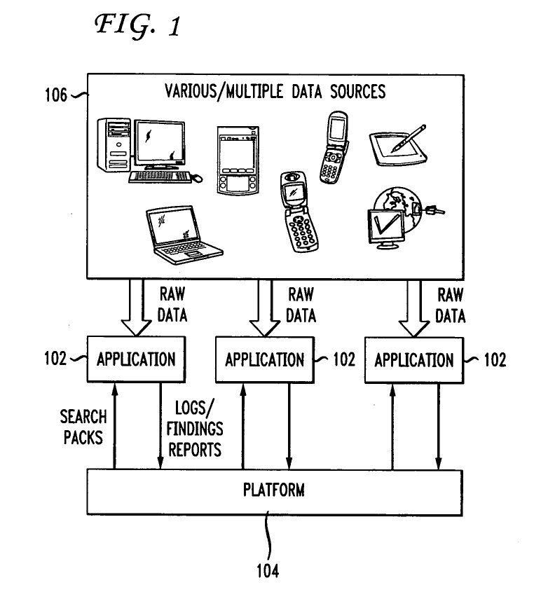

The platform, application and their interfaces according to various embodiments are shown in FIG. 1. Referring to FIG. 1, according to various embodiments, the platform 104 and application 102 can be used in a law enforcement and intelligence/counter-intelligence environment such as, for example, by law enforcement agencies (federal, state and local), intelligence agencies, Internet Service Providers (“ISP's”), portals, search engines, private investigation, and security firms conducting criminal investigations and intelligence data management. For illustrative purposes, at least one embodiment can be described with respect to criminal investigation and intelligence gathering. Various other embodiments can be illustrated with respect to use in corporate environments, public institutions, universities, or any other setting requiring an enterprise-wide solution for analysis of digital data by security experts involved in liability protection, and individuals involved with protection of proprietary intellectual property. The multiple various raw data sources 106 can be from any of the aforementioned environments and contexts.

Systems and methods in accordance with various embodiments can provide digital forensics and data identification functions to handle, for example: (1) the extraction of digital data; (2) the storage of relevant digital data; (3) the analysis and identification of the digital data; (4) the management of the digital data; and (5) the cross-agency or cross-company sharing of digital data including images and videos.

For example, the digital forensics and data identification application 102 can identify conclusive digital data coming from various digital sources. Conclusive data are any information decisive in whether to take further action. The identification of conclusive digital data can be realized by comparing the input data with pre-established sets of relevant data and also by searching the input data for pre-defined patterns. The analysis can be done automatically without human intervention. The application can compare multiple types of data, including text documents and multimedia files, with the pre-established sets. The application can also extract information from the input data in order to identify pre-defined patterns. The pre-established sets of relevant data and pre-defined patterns can be encapsulated in search packs.

With respect to various data sources 106, primary physical devices typically analyzed include hard drives, network attached storage devices, and storage area network devices. Primary data sources can include file systems, e-mail servers, databases, peer to peer network, or any other network protocols etc. Other physical devices can include USB keys, portable hand-held devices, cell phones, PDA's, digital cameras etc.

According to various embodiments, the data identification platform 104 of can be configured to manage the search packs. Platform 104 can enable the creation and update of search packs, maintain a repository of search packs, import and export search packs so they can be exchanged with other platforms, and consolidate findings after retrieving information from the data identification applications.

For example, in a criminal investigation environment, the data identification application 102 in FIG. 1 can be implemented, for example, in the following ways: i) Directly on the suspect computer where the computer is booted with the application distributed on a CD-ROM to bypass the native operating system (which could have been compromised) and accesses directly the local hard drives; ii) From a single computer which has a suspect hard drive, suspect drive media, or drive image connected directly to it; or iii) From a network server which can access drives, or drive image, stored on network attached storage devices, or other equivalent storage devices; and configured virtual drives, or drive image, available on a Storage Attached Network (SAN).

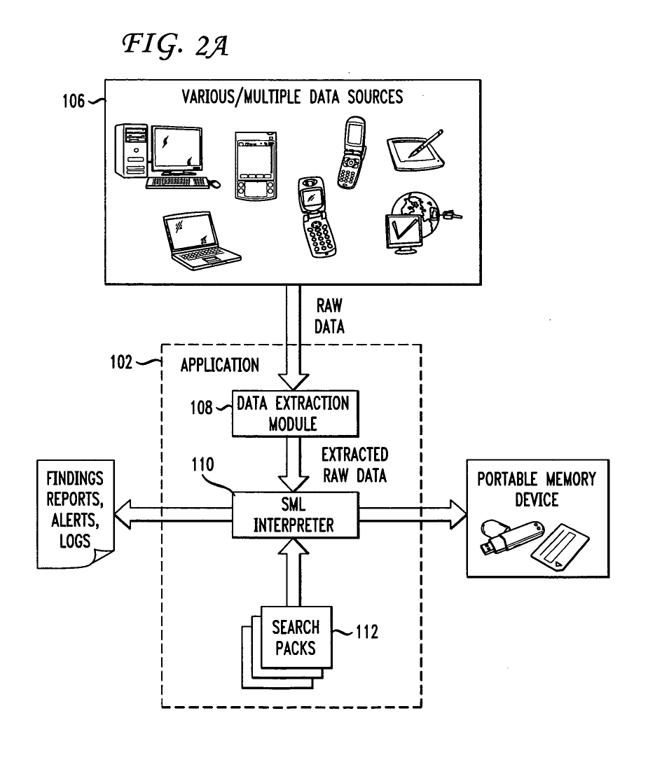

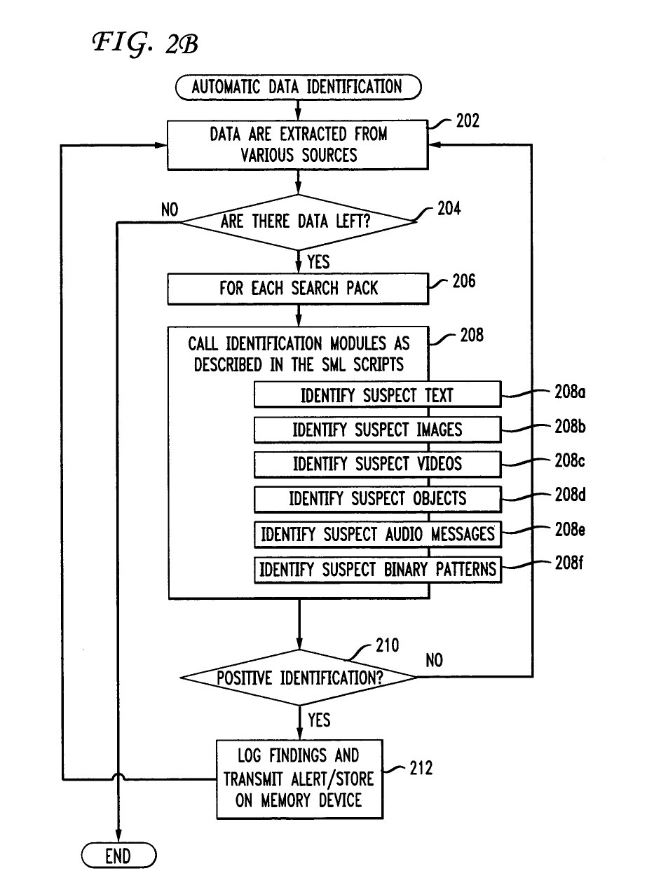

FIG. 2A is a block diagram showing in more detail digital forensic and data identification application 102 in accordance with various embodiments. Referring now to FIG. 2A, one input to application 102 can be raw data from various data sources 106 such as a hard drive or drive image. These raw data can be input to a data extraction module 108 of application 102.

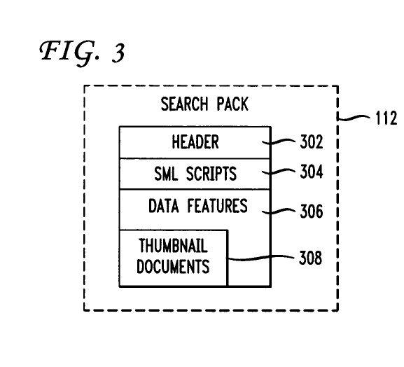

As shown in FIG. 1, one input to application 102 can be one or more search packs 112 originating from platform 104. Search packs are discussed in detail with reference to FIG.3. One component of a search pack can be a search markup language or “SML” program. An SML interpreter 110 can process the extracted, unknown raw data according to the instructions in the SML 112 contained in the search packs as shown in FIG. 3. This process can include comparing the raw, unknown data against known data contained in a search pack. The output can be provided in the form of, for example, one or more reports. Reports can include, for example, hardcopy printouts or computer screen displays containing findings reports, alerts, or logs.

According to various embodiments, application 102 can use multiple search packs 112 to perform data identification sequentially. Search packs do not have to come from a particular agency; they can be provided by any agency. Thus, during an investigation the data identification is performed not only with the agency's search packs but for the agent, concurrently and seamlessly with other agencies'search packs.

In accordance with various embodiments, application 102 can generate a report detailing the findings of the data analysis and data identification. The reports and findings can reference suspect files that triggered the match and a log. A report can be formatted in a manner most useful to the investigator or end user. Reports in their initial form are inadmissible in court as evidence. However, they can be verified by a qualified individual. For example, a chain of custody can be established and the report can be admissible as evidence in a criminal case. Initially, digital data that may be presented as evidence in court can be protected for data authenticity and integrity.

The steps of an automatic data identification process of the present invention are shown in FIG. 2B. Referring to FIG. 2B, at step 202 data can be extracted from raw data sources 106. As described above, these sources can vary widely and include any storage medium that can hold digital data. This extraction can be performed using techniques known to one of ordinary skill in the field. At step 204, the application can determine if there is any data to be extracted from any remaining data sources. If there is data left that needs to be identified, the process continues with step 206. If there is no data left, the process is complete.

Step 206 can occur for each search pack 112 in the application 102. For example, if there are ten search packs in an application, step 206 and all proceeding steps can occur ten times concurrently. The concept and advantages of search packs and the reasons why there would be multiple search packs are described below with respect to FIG. 3. At step 208, each search pack 112 can invoke its search markup language programs (described below) and call the identification modules in those programs. This can be performed by SML interpreter 110. At step 208, the following identification processes can take place for the automatic identification of suspect data: identify suspect text 208a; identify suspect images 208b, identify suspect videos 208c, identify suspect objects 208d, identify suspect audio messages 208e, and identify suspect binary patterns 208f. In various other embodiments, additional identification modules can be invoked for various types of data not shown in FIG. 2B or in the other figures.

Each one of these modules can be specialized in identifying a certain type of data. They all take the data extracted from data sources 106 and compute relevant features on these data and then compare these features to the ones contained in the data features portion 306 of search pack 112. In the described embodiment, features can be quantitative characteristics of files having multimedia content computed or derived from the content of the files instead of the files binary structure. Depending on the type of identification needed, different features can be extracted and compared. For example, in character recognition, features can include horizontal and vertical profiles, number of internal holes, stroke detection and many others. In another example, in speech recognition, features for recognizing phonemes can include noise ratios, length of sounds, relative power, filter matches and others. In at least one embodiment, the ability to compare the content of multimedia files, whether visual or auditory, can rely on the ability to extract these discriminating and independent features from the files. The extracted features can then be compared with previously extracted features.

Returning to FIG. 2B, when one or more key features match, as determined by each identification module, the data can be positively identified as suspect. If there is a positive identification at step 210, the findings can be logged and an alert transmitted at step 212, and control returns to step 202 where data are extracted from various sources. If there is no positive identification, control also returns to step 202. The process can continue until there are no data left as determined at step 204.

In accordance with various embodiments, the data extraction process, and SML interpreter execution described above, using the same data sources and search packs, can produce the same results regardless of the computing device. This is relevant to Federal Rule of Evidence 901(b)(9) which provides a presumption of authenticity to evidence generated by or resulting from a largely automated process or system that is shown to produce an accurate result. Furthermore, to satisfy the “Best Evidence Rule” and more specifically Evidence Rule 1001(3), the reports also contain the context of any alerts and matches.

Application 102 can rapidly scan unknown input data. For images, application 102 can use a search pack to identify any images in the unknown data that may be illegal or conclusive. For example, if there is an image in the unknown data that matches or is visually similar to a known child exploitation photo, a known counterfeit currency note, or a known photo of a suspected terrorist, etc. As long as one of the search packs contains these known images, they will be identified in the unknown data. Any images, or, more generally, any data that matches or are similar are referred to as either suspect image/data or friendly image/data. The same is true for video and audio files. Unknown video and audio files can be partially matched against known videos or still images and audio files.

Various embodiments supplement conventional text-based searches and hash matching algorithms with semantic, hash-based technologies to automate a detection process for identifying known suspect files as well as identifying disparate relationships between known suspect files and other similar files.

In various embodiments, an advanced analysis using digital forensic and data identification application 102 performs functions in addition to those in a standard analysis. These functions can include extracting and comparing semantic information from the data files and disk areas of the inputted data source. More specifically, an advanced analysis can involve: 1) using altered semantic hash functionality to automatically identify altered multimedia files; and 2) using series semantic hash functionality to automatically identify multimedia files that belong to a predefined series.

When application 102 is distributed on a CD-ROM and used directly on the suspect computer, it performs the following specific tasks:
Boot the suspect computer with a specialized operating system (thereby not relying on the installed operating system which could have been compromised),
Compute checksums of the hard drives before and after the analysis to verify the non invasive analysis process,
Log all input/output errors that might have occurred during data extraction and acquisition,
Copy the identified suspect files and the findings report on a portable media drive (e.g. USB key).

When application 102 is used from a single computer which has a suspect hard drive, suspect drive media, or drive image connected directly to application 102 performs the following specific tasks:
Access the attached hard drive or hard drive image,
Compute checksums of the input media before and after the analysis to verify the non invasive analysis process,
Copy the identified suspect files and the findings report on the examiner's computer.

When application 102 is deployed on servers which can access drives it has the following specific features:
It can be deployed on multiple servers in order to accommodate the input data increase,
It can use resource intensive hash computation,
It can accommodate more various input sources.

Among the numerous components of FIG. 1 and FIG. 2A is search pack 112, a software component that resides in platform 104 and application 102. FIG. 3 shows components of a search pack 112 according to various embodiments. As shown in FIG. 3, search pack 112 contains a header 302, one or more SML script 304, and data features 306. In the criminal investigation and intelligence agency context, a search pack 112 is designed and prepared by an individual involved in a case and is created with an investigative goal in mind, for example, a passport investigation, tracking a child exploitation ring, gathering leads on a counterfeiting operation, and so on.

A search pack should: 1) be dedicated to a specific subject or case; 2) be as comprehensive as possible on the subject/case; and 3) be updated continuously as new intelligence or information about the case is learned. A search pack is essentially a digital snapshot of a case and contains all relevant data about a case.

In the context of an intelligence agency, such as the FBI, where users of the present invention will typically include agents, analysts, and examiners, search packs are created by agents to simplify and accelerate the examiner or agent's task in the field, e.g. at a crime scene or some other remote location, by automating the file analysis process.

As FIG. 3 shows, a search pack 112 can have three basic sections: data features 306, SML scripts 304, and a header 302. Header 302 contains information such as contact information, confidentiality level, agent ID, and any other information needed to contact the person in charge of the search pack (e.g., the agent responsible for the case, a national expert on a specific subject, etc). Header section 302 of the search pack contains critical information used to identify the search pack, track modifications, detail access rights when sharing the search pack, and contains contact information. The contact information becomes very relevant when suspect data are identified while running another agency's search pack. In this situation the examiner performing the analysis can communicate with the other agency's contact to inform him/her of the situation.

SML script 304 makes it possible to describe complex searches that the search pack designer/creator wants performed on any incoming raw data. Search pack 112 can be specialized for a specific purpose. For example, a search pack can have the sole purpose of eliminating from incoming raw data any data that are “friendly,” thus removing them from further investigation and saving time for an investigator. As described in more detail below, this can be done by including standard and semantic hash values of these friendly data, often contained in files (e.g., operating system files, application files) in a search pack. Data features 306 contain features extracted from known suspect files. These features can be hash values, as described above, when images or binary files are being compared. The features can also be document templates when text documents are matched or audio signatures when matching audio files. Another example of a specific purpose is detecting recurring patterns of illegal activities, such as activities stemming or resulting from a standard counterfeiting toolkit or a standard hacker toolkit. Other examples include:
Detecting a specific context or situation (criminal, intelligence, etc.) with names, addresses, and pictures of places and people.
Detecting general threats by containing pictures, blueprints and addresses of public buildings and structures that are potential terrorist targets.
Comprehensive set of images on a precise subject (e.g. child exploitation).
Detecting copyrighted material like movies or audio albums.
Detecting file extension anomalies.
Perform entropy tests to identify encrypted files.
Recognize the language of a textual document.

One sub-component of a search pack contains thumbnails of images or video 308 if the search pack creator decides to include them. With these original images an investigator can verify that a match is accurate. In the case of video, there can be one thumbnail for the whole video or one for each relevant frame.

A hash function is applied to all known data which includes text, images, and video. As is known to someone of ordinary skill in the field, there are numerous existing hash functions and new ones can be created. Existing ones include binary, altered semantic, and series semantic. New or future modules for hash functions may include, for example, hash functions for facial recognition. A hash value is a fingerprint or a digital signature of the content of a file and, therefore is derived from the content of a file. In the described embodiment, there are three different types of hash values or “signatures”:
Binary hash value is a unique cryptographic message digest value, like MD5 or SHA-1. It can be computed on any file type. It is used to determine if a file has been altered by comparing its hash value to the hash value of the original file.
Altered semantic hash value is a proprietary hash type based on the semantic content of the file, not on its binary content. This hash works for textual documents, images, audio, and video files and makes it possible to detect altered versions of the same file.
Series semantic hash value is a proprietary hash type also based on the semantic content of the file, not on its binary content. This hash works for textual documents, images, audio, and video files and make it possible to detect files that are part of a series.

In various embodiments, a search pack can reference other search packs. This feature is useful to specialize a search pack without having to duplicate the entire content of the original search packs, and particularly their data sections. For example, a “counterfeit” search pack could be created based on the content of the “currency” and the “passport” search packs.

When creating a search pack, an investigator:
Decides which known data and files are relevant to the investigative goal and should be in the search pack.
Decides which hash value type or types should be created for each file (binary and or semantic), and if a multimedia file, whether a thumbnail or other visual should be included in the search pack.
Decides what the search conditions for the investigative goal should be and creates the SML script.
Enters meta-data information e.g. contact information, security level, etc.

All content of a search pack can be modified to reflect changes in an investigation. Investigators, such as Examiners, Case Agents, and Field Agents, can download updates to search pack 112 directly from platform 104 as shown in FIG. 1. However, hash values cannot be edited directly; the underlying data or file must be modified. When a modification occurs, the version number of a search pack is updated. This is useful during synchronizations between the platform 104 and application 102. To avoid redundancy during search pack synchronization, downloads, and updating via CD, when a search pack is obsolete or no longer useful or is simply replaced or incorporated in another one, it can be removed from platform 104.

Search packs can be distributed by agencies to Internet service providers, portals and search engines, among other entities. These entities can utilize search packs to scan email exchanges and detect any known illegal data in these emails that match hash data sets in the search packs. In addition to emails, search packs can also be applied to images posted on dating sites, social networking sites, and community sites as these images may be relevant to crimes such as child exploitation, theft ID, and counter-intelligence.

Search pack 112 is an encapsulation of all the elements necessary for automatic digital forensic analysis and data mining in platform 104 and application 102 of the present invention. The principal strength of a search pack is that it does not contain directly readable or modifiable sensitive information but rather contains a safe representation (in the form of hash values) of sensitive information. This makes it possible to share search packs among agencies, organizations or other groups without risking a leak of critical information.

As described above, search conditions are programmed in SML, an XML-based language and contained in SML programs or scripts 304. In the described embodiment, an SML interpreter 110 executes the SML scripts contained in a search pack. More specifically, the SML interpreter 110 executes a series of SML instructions. SML allows an investigator to precisely describe conditions for identifying data that are useful or relevant to an investigation. Several examples of specialized search packs are described herein.

The “specialization” is often embodied in the SML script of a search pack. SML allows an investigator to describe very specific or specialized conditions and allows for a broad range of analysis. For example, an SML program can be written to only identify images that have a resolution of over 100 dpi. Other conditions on image properties (e.g. EXIF data or image file types) can also be applied to further refine a condition, such as image properties, hash sets, occurrences of words and phrases, and so on. Specific SML phrases can be grouped together by logical operators (AND, OR) making it possible to build complex conditions. It should also be noted that a condition may not involve a hash. To illustrate, take the following search criteria:

“If the submitted file is an image that has a resolution over 300 dpi, where the AUTHOR EXIF field contains information and matches with at least one video of this search pack then trigger an alert”

The SML for this search may be:

```
<condition id=”cond1”>
    <file-prop type=”image”/>
    <img-prop res=”300” op=”gt”/>
    <img-mdata field=”author” value=”*”/>
    <ash-match group-id=”videos”/>
</condition>
```

In various embodiments, SML interpreter 110 is able to interact with other modules for completing specific tasks. Examples include: an optical character recognition (OCR) module which accepts video files and returns words or phrases extracted from the video; hash indexers (e.g., binary hash indexer, semantic hash indexer) which accepts files and returns hash values; and hash comparators which compares hash values. Search packs together with other technologies are expandable to integrate external third-party technologies and software, such as OCR technologies.

As shown in FIG. 1, a digital forensics and data identification platform 104 operates with one or more digital forensics and data identification applications 102. Platform 104 can be seen as a server application and application 102 is a client application. The application 102 and platform 104 can have a complimentary relationship, and both utilize search pack and SML, although in somewhat different capacities. In the context of a criminal investigation and intelligence gathering organization, such as the FBI or Secret Service, platform 104 is intended to be used by investigators and, in addition, is accessible and supervised by information technology (IT) staff. With respect to the investigators, those who work in a setting such as a regional or home office and use computers that are connected to a network would use digital platform 104 while those on the field or in remote locations investigating a case or gathering intelligence would use digital application 102 in a portable CD-ROM format or on portable computers. For analysis of large volumes of data, the network server application can be used.

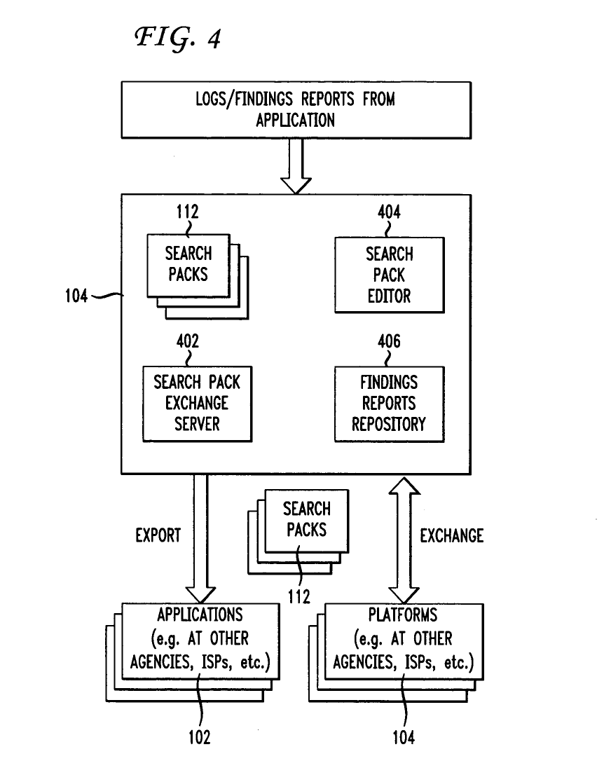

FIG. 4 is a block diagram showing a data identification platform 104 according to at least one embodiment wherein platform 104 can be used for storing, categorizing, and disseminating search packs 112. Platform 104 can host search packs and can import and export search packs from other platforms or applications using search pack exchange server 402. It also manages and catalogs search packs. A search pack editor 404 coordinates the creation and editing of search packs. Platform 104 can also manage the use of them among investigators thereby facilitating the exchange of information between agencies, as well as centralizing reports and findings, and consolidating investigation logs. Investigation logs from application 102 can be uploaded to platform 104 to allow the investigators to review the consolidated logs.

As the number of search packs grows, platform 104 offers more functionality to search through them based on their content. It is also possible to update multiple search packs in a single operation. Another management feature is the ability to compare two search packs to determine how similar they are to avoid duplication and facilitate management. Comparing two search packs is possible even if they have been created by a different platform as the comparison is done on their data, without the need to access the original files. Similar search packs may also imply that different agencies may be working on the same cases.

In various embodiments, a single entity, such as a government agency or a sub-division of an agency typically will have installed a single digital forensics and data identification platform 104 as shown in FIGS. 1 and 4 for use only within that agency, group, sub-division, etc. In such embodiments, there can be cross-platform sharing among agencies or entities, each running its own copy or version of platform 104. This allows an agency or enterprise to decide which of its data it wants to share with other entities, thus allowing data sharing without compromising intra-agency confidentiality requirements. In various other embodiments, an agency or other entity can use multiple digital forensic platforms 104 in its IT environment. In at least one other embodiment, regional or other agencies do not have to install platform 104 in order to execute a search pack 112 on an application 102.

One of the primary functions of platform 104 is allowing the creation and editing of search packs using search pack editor 404. For example, in the FBI, an Analyst or Examiner would normally create, update, or delete a search pack based on the initiation or progress of an investigation. This can be done on the platform and then disseminated to Field or Case Agents who are using search packs on digital forensic and data identification application 104.

With respect to data sharing, platform 104 supports the exchange of search packs among entities, for example, via CD or search pack downloads. Given that search packs contain not only known data in the form of text, video, images, etc., but also strategic search conditions encoded in SML (recall that search packs are created with an investigative goal in mind), entities can share this strategic information and perspective about cases as well.

Search pack distribution can be controlled by allowing application 102 to download and decrypt only those search packs belonging to platform 104 associated with the application. A first platform 1 can import a search pack from a second platform 2, at which point the search pack also belongs to platform 1 for the purposes of search pack distribution control (it still belongs to platform 2). This distribution control mechanism is enforced in two steps: 1) when the application connects to the platform, the application has to provide the correct credential to the platform before being able to download a search pack from the platform (this prevents an application from Agency A to connect to a platform from Agency B); and 2) once a search pack is downloaded, the application must share the same cryptographic key with the platform in order to decrypt the search pack.

When application 102 is transferring user activity logs, which may contain sensitive, analyzed data to platform 104, a network connection, such as a VPN, is established to ensure privacy. Search packs are encrypted when stored on the platform and decrypted only when they need to be modified.

The application 102 and the platform 104 can authenticate users and log their activities. In various embodiments, platform 104 has an internal mechanism that authenticates users manipulating search packs (for creation, update, import, export). In various embodiments, a user is not authenticated with the application. In embodiments where the Microsoft Windows operating system is used, the application uses a Windows login program to log the user's activity and to establish connections with the platform.

The platform 104 can have a user interface for creating, editing and importing/exporting search packs. The platform 104 can have a Web based user interface that allows users to utilize a platform's functionality. An investigator or user can create a search pack, edit SML, generate hash values, enter meta-data such as general information, contact information, thumbnails, etc. via an application interface and a platform interface. For example, when generating hash values, the investigator can select and places files via the interface for which hash values are needed (text, image or video files) in a folder and select which type of hash functions should be performed on which files.

In various embodiments, all users'activities can be logged by application 102 or by platform 104. These activities include: login information; data acquisition; automatic searches performed and important results found; report activity; manipulation of files; and any error encountered by the application.

Pervasive throughout the platform and application is the manipulation of sensitive data. Data are secured at each stage of data creation, modification, transfer/exchange, and storage. The platform also authenticates users and logs activity. When a search pack is disseminated to investigators within an agency or to other agencies, or to other organizations or entities, a search pack satisfies the following security requirements: 1) confidentiality: ensuring that search pack content cannot be accessed by unauthorized people, this is achieved by encrypting the content; 2) integrity: ensuring that the content has not been modified without making an activity log entry which is achieved by integrating a checksum; and 3) authenticity: ensuring that the creator of a search pack can be authenticated, this is achieved by integrating digital signatures.

Platform 104 and application 102 create numerous files, each of which may contain critical information that needs to be protected against external modifications. In various embodiments, the files contain encrypted checksums thereby ensuring their integrity. Investigators and other end users also create several categories of files containing sensitive data (log files, case files, hard-drive images, etc.) that are protected against external modifications. In at least one embodiment, this is done by using encrypted checksums in the files. Any modifications of those files occurring within the application are logged thereby guaranteeing the files'integrity.

In various embodiments, the platform 104 and application 102 can be used in corporate environments, public institutions, universities, or any other setting requiring an enterprise-wide solution for analysis of digital data by security experts involved in, for example, Digital Liability management, Digital Rights management, and Extrusion detection. In various other embodiments, they are also used in a law enforcement and intelligence/counter-intelligence environment by law enforcement agencies (federal, state and local), intelligence agencies, Internet Service Providers (“ISPs”), private investigation, and security firms conducting criminal investigations and intelligence data management.

The following exemplary embodiments are directed to digital liability management, digital rights management and extrusion detection contexts including digital forensics and data identification to handle (1) the extraction of digital data; (2) the storage of relevant digital data; (3) the analysis and identification of the digital data; (4) the management of the digital data; and (5) the cross-company or cross-agency sharing of digital data including images and videos. In such various embodiments, the application 102 can be configured to identify conclusive digital data coming from various digital sources. Conclusive digital data is any information decisive in taking further action whether in a criminal investigation or digital liability management context.

In various embodiments, the identification can be realized by comparing the input data with pre-established sets of relevant data and also by searching the input data for pre-defined patterns. The analysis can be done automatically without human intervention by comparing multiple types of data including text documents and multimedia files to the pre-established sets. Embodiments can also extract information from the input data in order to identify pre-defined patterns. The pre-established sets of relevant data and pre-defined patterns for identification can be encapsulated in search packs.

A search pack can: 1) be dedicated to a specific subject or potential violation; 2) be as comprehensive as possible on the subject/potential violation; and 3) be updated continuously as new intelligence or information about the potential violation is learned. A search pack is essentially a digital snapshot of a potential violation and contains all relevant data about the violation. In the context of a commercial organization where users of the present invention will typically include security or corporate liability experts, search packs are created by these experts to enforce Digital Liability, Digital Rights and Extrusion prevention policies by automating the data identification process.

Referring again to FIG. 3, a search pack in accordance with at least one embodiment can have three basic sections: a header, the asset data features, and SML scripts. The header contains information such as internal company contact information, and any other information needed for the first point of contact regarding this potential violation. The asset data features are relevant information extracted from the assets making it possible to identify such assets during the data identification process. The search pack can include protected asset features. The SML script makes it possible to describe complex searches that the search pack designer/creator wants performed on any incoming raw data.

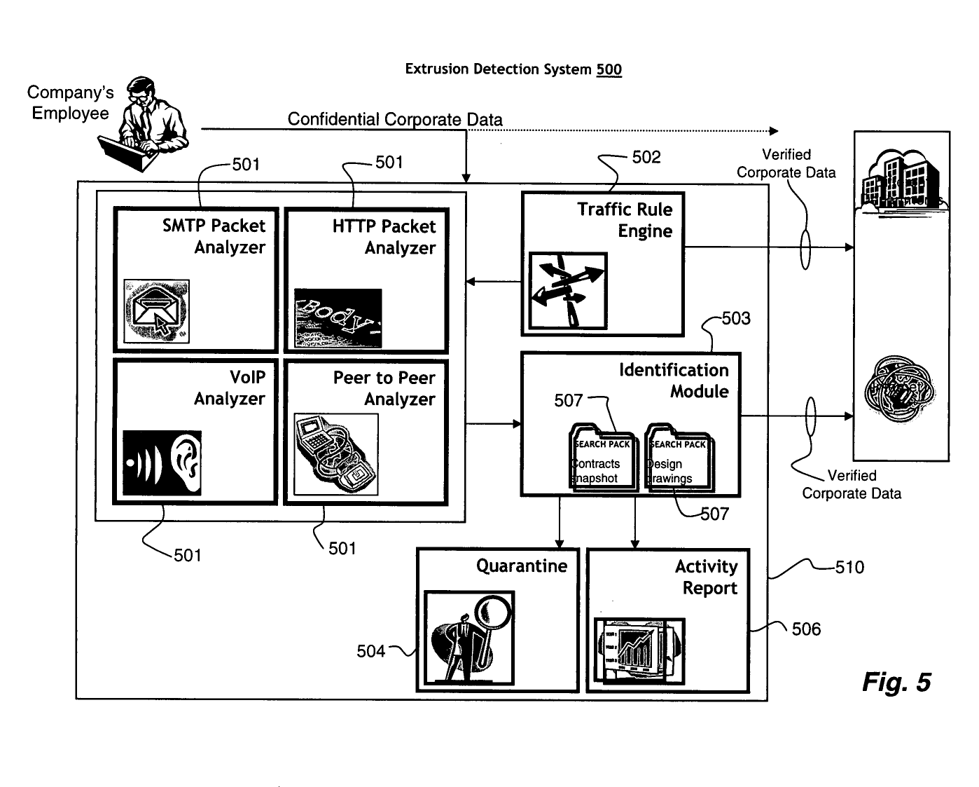

In various embodiments for digital liability management, digital rights management and extrusion detection contexts, a host system 510 can be configured to provide an extrusion detection system 500 as illustrated in FIG. 5. As shown in FIG. 5, the extrusion detection system 500 can comprise a plurality of analysis modules 501 and a traffic rule engine 502. The traffic rule engine 502 can be coupled to the analysis modules 501 and may include one or more preset rules. In various embodiments, the traffic rule engine 501 can be configured to select, based on the preset rules, an incoming data packet for extrusion analysis by at least one of the analysis modules 501.

Further, each one of the analysis modules 501 can be configured to extract information from an incoming data packet in accordance with a particular protocol.

The extrusion detection system 500 can further comprise an identification module 503 and a quarantine datastore 504. The identification module 503 can include one or more identification components 507. For example, each identification component 507 can be a search pack, such as, for example, the search pack 112 comprising a header, a search markup language program, and a data features section containing features of data. For example, the search packs 507 can be configured to identify contracts data and design drawings.

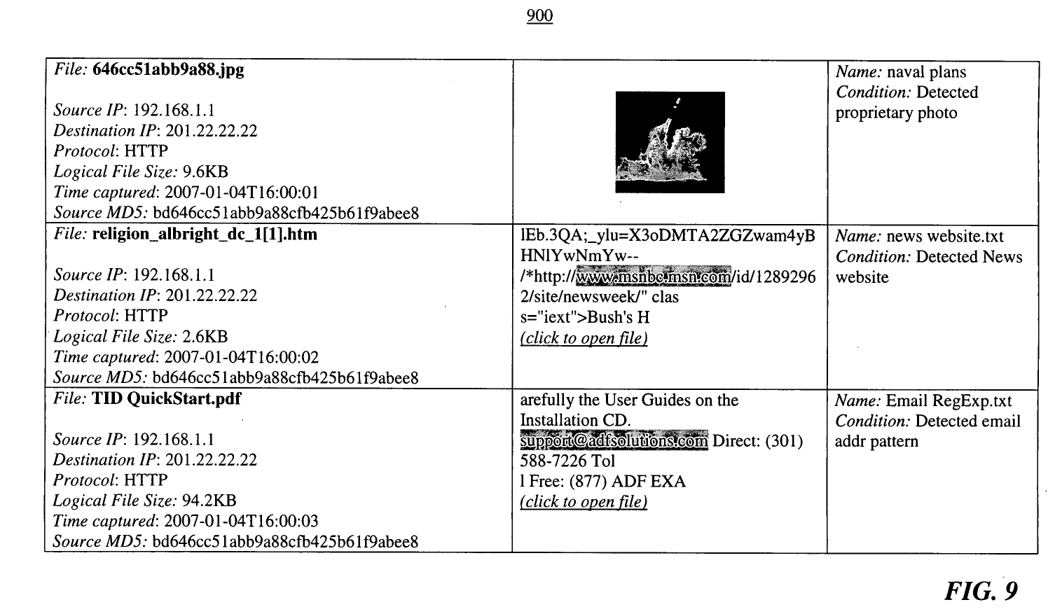

According to various embodiments, the identification module 503 can be configured to identify suspect data using the identification components 507. In various embodiments, the identification module 503 can also be configured to output activity reports 506 based on suspect data and to maintain suspect data using a quarantine datastore 504. FIG. 9 is an extrusion detection report 900 example of an activity report 506 according to various embodiments. As shown in FIG. 9, the extrusion detection report can include various information such as, for example, filename, source Internet Protocol (IP) address, destination IP address, file size, time captured, source MD5, suspect image or text, and a category or condition.

In various embodiments, the identification module 503 can be implemented using a sequence of programmed instructions that runs continuously and exists for the purpose of handling periodic service requests that the identity module 503 expects to receive. For example, the sequence of programmed instructions can comprise a daemon program configured to forward the requests to other programs (or processes) as appropriate.

Thus, the extrusion detection system 500 shown in FIG. 5 can provide a system for detecting when proprietary information leaves its authorized realm through the network.

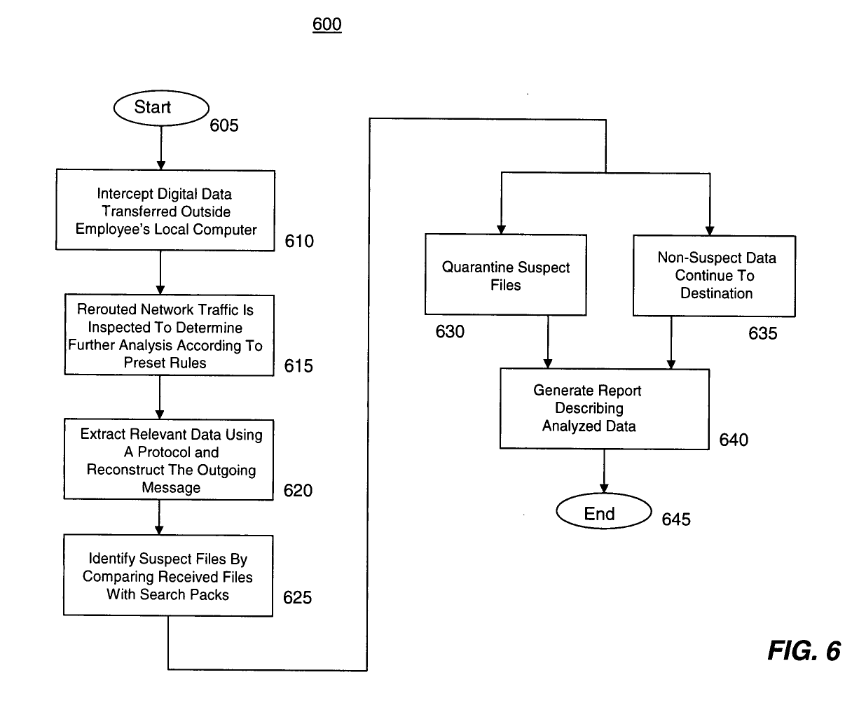

FIG. 6 is a flow chart of an extrusion detection method 600 according to at least one embodiment using the extrusion detection system 500 of FIG. 5. Referring to FIG. 6, the method 600 can commence at 605 and proceed to 610. At 610, intercepting digital data received from a local computer of an employee who knowingly or unknowingly transfers confidential digital data outside of his/her computer. For example, the destination of the data can be the Internet or the intranet to someone who is not supposed to obtain these data. To transfer the files, the employee can be using an application such as, for example, an email client application, a web mail, an instant messaging program, a peer to peer application, a File Transfer Protocol (FTP) client application, a Samba client application, or any other application making it possible to exchange data between computers.

Control can then proceed to 615, at which network traffic is rerouted to the traffic rule engine for inspection to determine which part of the network traffic (for example, relevant data) will be analyzed based on preset rules. The preset rules can restrict the analysis to data coming from a local area network, or going to a specific destination. The rest of the traffic follows its normal course without being analyzed.

Control can then proceed to 620. At 620, the active analyzer modules extract the relevant data from the network traffic, received from the traffic rule engine, and reconstruct the outgoing message. In various embodiments, each active analyzer module can be specialized in a particular protocol. For example, the active analyzer modules 501 can decode, for example, but not limited to, Simple Mail Transfer Protocol (SMTP), Session Initiation Protocol (SIP), Network File System (NFS), Samba, File Transfer Protocol (FTP), HyperText Transfer Protocol (HTTP), Jabber, and Gnutella. Once the message is reconstructed, the files can be extracted and forwarded to the identification module 503, at 625.

At 625, the identification module 503 can receive the files with their source and destination information, and can begin the identification process. In at least one embodiment, all of the files are compared with the deployed search packs to determine if a suspect file is transiting on the network.

If a positive identification is found in 625, then control can proceed to 630 and 635. At 630, the suspect files are put in quarantine for the security officer to review and decide on the follow up action. At 635, data that has not been identified as being suspect continues its course to its final destination.

Control can then proceed to 640, at which the identification module generates a complete report detailing the data analyzed and the data in quarantine. In accordance with various embodiments, the output presentation of the data, via hardcopy printout or computer screen display, for example, makes it easy to track the source and the destination, analyze the frequency of such exchanges, and display the suspect files. Control can then proceed to 645, at which method 600 can end.

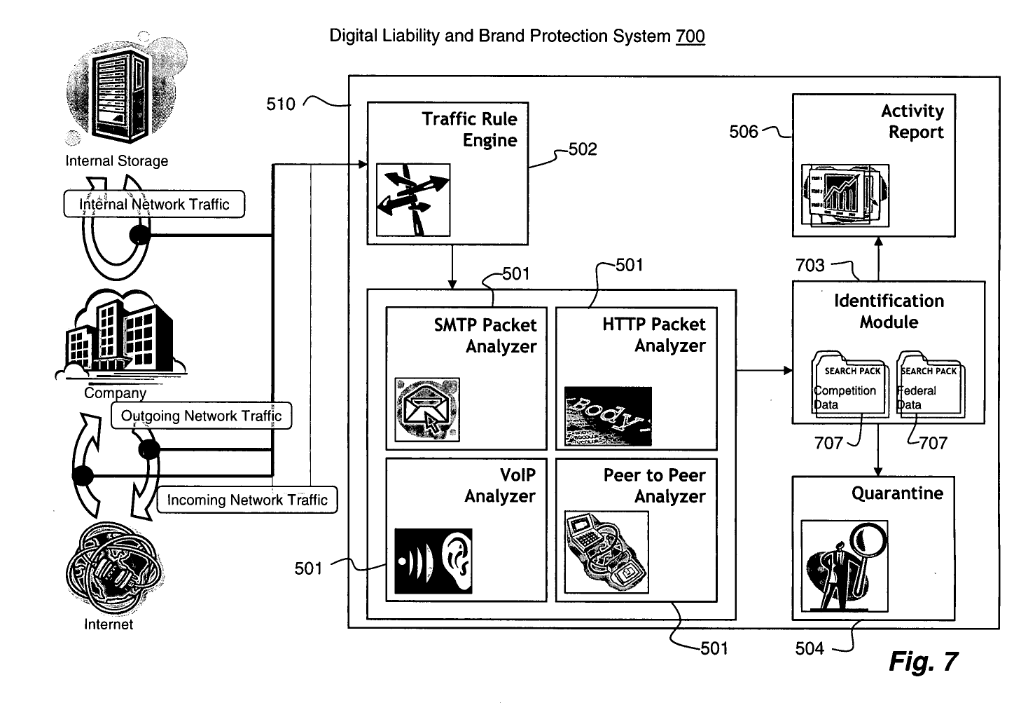

FIG. 7 is a digital liability and brand protection management system 700 in accordance with at least one embodiment. Referring to FIG. 7, the digital liability and brand protection management system 700 can be configured to provide digital liability and brand protection management system 700. In particular, the digital liability and brand protection management system 700 can be configured to monitor the network traffic within the company and coming in and out to ensure that no illegal or compromising data is present within the company.

As shown in FIG. 7, the digital liability and brand protection management system 700 can comprise a plurality of analysis modules 501 and the traffic rule engine 502. The traffic rule engine 502 can be coupled to the analysis modules 501 and may include one or more preset rules. In various embodiments, the traffic rule engine 501 can be configured to select, based on the preset rules, an incoming data packet for digital liability or brand protection management by at least one of the analysis modules 501. Further, each one of the analysis modules 501 can be configured to extract information from an incoming data packet in accordance with a particular protocol.

The digital liability and brand protection management system 700 can further comprise a digital liability and brand protection identification module 703 and the quarantine datastore 504. The identification module 703 can include one or more identification components 707. For example, each identification component 707 can be a search pack, such as, for example, the search pack 112 comprising a header, a search markup language program, and a data features section containing features of data. According to various embodiments, the identification module 703 can be configured to identify protected assets data using the identification components 707, and can also allow sharing of the suspect data among a first entity and at least a second entity in a manner that enables utilization of the suspect data by the second entity while not revealing the actual content of the sensitive data to the second entity. In various embodiments, the identification module 703 can also be configured to output reports 706 based on suspect data and to maintain suspect data using a quarantine datastore 504.

These system 700 components can be configured as shown and described with respect to FIG. 5 except as otherwise described. For example, in the digital liability and brand protection management system 700, the reports 706 can include a global map of where the protected assets are located and where they transit is presented to the user. Further, the search packs 707 can be configured to identify competition data and federal data, for example.

Furthermore, in various embodiments directed to brand protection or asset protection, the system 700 may be used by, for example, companies A and B which have created search packs 707 containing confidential information that they want to protect or do not want to have hosted or to be present on the ISP's servers. By deploying those search packs 707 to the storage servers of an Internet Service Provider (ISP), or to a computing platform coupled thereto, the companies can be contacted when positive identification is established, protecting the ISP from the liability of hosting confidential or copyrighted content and allowing the companies to track their assets. In such embodiments, the search packs 707 can be created and/or obtained from the content-providing entity.

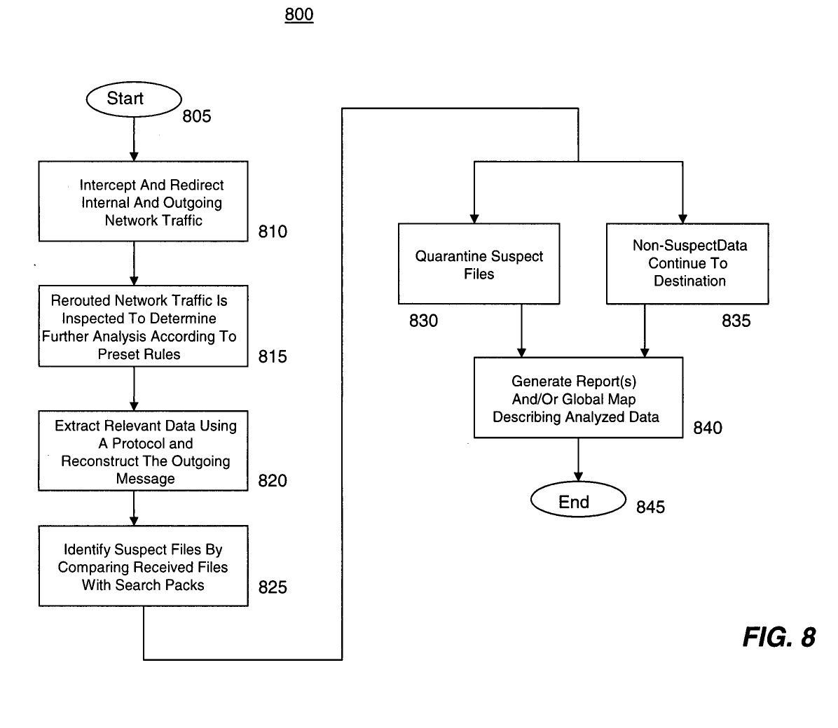

FIG. 8 is a flow chart of a digital liability and brand protection management method 800 according to at least one embodiment using the digital liability and brand protection management system 700 of FIG. 7 to monitor the network traffic within the company and coming in and out to ensure that no illegal or compromising data is present within the company. Referring to FIG. 8, the method 800 can commence at 805 and proceed to 810. At 810, internal network traffic and outgoing network traffic is intercepted and redirected to the traffic rule engine. In at least one embodiment, the incoming network traffic can be intercepted before it reaches any workstation or server and redirected to traffic rule engine.

Control can then proceed to 815, at which network traffic is rerouted to the traffic rule engine for inspection to determine which part of the network traffic will be analyzed based on preset rules. Rules can restrict the analysis to data coming from a local area network or certain URLs, or going to a specific destination inside or outside of the company's network. The rest of the traffic follows its normal course without being analyzed.

Control can then proceed to 820. At 820, the active analyzer modules extract the relevant data from the network traffic, received from the traffic rule engine, and reconstruct the outgoing message. In various embodiments, each active analyzer module can be specialized in a particular protocol. For example, the active analyzer modules 501 can decode, for example, but not limited to, SMTP, SIP, NFS, Samba, FTP, HTTP, Jabber, Gnutella. Once the message is reconstructed, the files can be extracted and forwarded to the identification module, at 825.

At 825, the identification module can receive the files with their source and destination information, and begin the identification process. In at least one embodiment, all of the files are compared with the deployed search packs to determine if a suspect file (for example, a file containing a protected asset) is transiting on the network. In various embodiments directed to brand protection or asset protection, the search packs 707 can identify content that a content provider does not want to have hosted or to be present on the servers.

If a positive identification is found in 825, then control can proceed to 830 and 835. At 830, the suspect files are put in quarantine for the security officer to review and decide on the follow up action. At 835, data that has not been identified as being suspect continues its course to its final destination.

Control can then proceed to 840, at which the identification module generates a complete report detailing the data analyzed and the data in quarantine. In accordance with various embodiments, the output presentation of the data, via hardcopy printout or computer screen display, for example, makes it easy to track the source and the destination, analyze the frequency of such exchanges, and display the suspect files. For example, the reports can include a global map of where the protected assets are located and where they transit is presented to the user. Control can then proceed to 845, at which method 800 can end.

According to various embodiments, the extrusion detection system 500 and the digital liability and brand protection management system 700 can be implemented as a sequence of programmed instructions executed using a host system 510. The host system 510 can comprise a computer workstation that includes at least a processor, internal memory, external non-volatile memory, input/output interfaces, and software components including an operating system and standard set of application programs in addition to the instructions comprising the extrusion detection system 500 and the digital liability and brand protection management system 700. For example, the host system 510 may include a hardware computing platform such as the Ultra 25 Workstation available from Sun Microsystems, Inc. of Santa Clara, Calif. Further, the host system 510 may include a Unix-based operating system such as, for example, Linux™, Solarix™ available from Sun Microsystems, Inc., or Berkeley Software Distribution (BSD) Unix or its variants such as the Mac OS X™ operating system available from Apple Computer, Inc. of Cupertino, Calif. Alternatively, the host system 510 may use the Windows NT™ operating system available from Microsoft Corporation of Redmond, Wash.

In various embodiments, the analysis modules 501, traffic rule engine 502, and identification module 503 can be implemented using a sequence of programmed instructions. In particular, in various embodiments, the identification module 503 can be configured to run continuously to handle periodic service requests that the identity module 503 expects to receive. For example, the sequence of programmed instructions of the identity module 503 can comprise a daemon program configured to forward the requests to other programs (or processes) as appropriate.

In addition to standalone embodiments, the host system 510 can also be implemented across multiple computing systems such that the various functions described herein are performed in a distributed computing environment.

Furthermore, the host system 510 may operate in conjunction with the application 102 and platform 104 as described herein. For example, search packs 507 or 707 used with the host system 510 may be created or edited using the search pack editor 404 of the platform 104. Furthermore, search packs 507 and 707 may be cataloged and/or distributed to the systems 500 or 700, respectively, using the platform 104.

Although the above description may contain specific details, such details should not be construed as limiting the claims in any way. Other configurations of the described embodiments of the invention are part of the scope of this invention. Accordingly, the appended claims and their legal equivalents define the invention, rather than any specific examples given.

What is claimed is:

1. An extrusion detection system, comprising:
a plurality of analysis modules and a traffic rule engine, wherein the traffic rule engine is coupled to said plurality of analysis modules and comprises preset rules, the traffic rule engine being configured to select, based on said preset rules, an incoming data packet for extrusion analysis by at least one of the plurality of analysis modules;
wherein each said analysis module is configured to extract information from said incoming data packet in accordance with one of a plurality of protocols; and
an identification module including one or more identification components comprising a header, a search markup language program, and a data features section containing features of data, wherein the identification components are configured to identify suspect data and to allow sharing of said suspect data among a first entity and at least a second entity in a manner that enables utilization of the suspect data by the second entity while not revealing the actual content of sensitive data to the second entity;
wherein said identification module is configured to output a report based on at least said suspect data.

2. The extrusion detection system of claim 1, wherein the suspect data is conclusive data.

3. The extrusion detection system of claim 1, wherein the features of data cannot be directly modified by the second entity.

4. An extrusion detection method, comprising:
intercepting network traffic including digital data received from a local computer;
rerouting the intercepted network traffic to a traffic rule engine;
inspecting the rerouted traffic using preset roles to determine a part of the rerouted traffic to be analyzed;
extracting, using a particular protocol, the determined part of the rerouted traffic to be analyzed from the network traffic and reconstructing the outgoing message;
identifying suspect files transiting on the network by comparing the extracted traffic with one or more search packs to determine if a suspect file is transiting on the network, wherein said one or more search packs comprise a header, a search markup language program, and an asset data features section; and
outputting an activity report.

5. The extrusion detection method of claim 4, in which the header contains internal company contact information.

6. The extrusion detection method of claim 4, wherein the preset rules can restrict the analysis to data coming from a local area network or going to a specific destination.

7. The extrusion detection method of claim 4, wherein the particular protocol is a communication protocol.

8. The extrusion detection method of claim 7, wherein the communication protocol is selected from the following: SMTP, SIP, NFS, Samba, FTP, HTTP, Jabber, and Gnutella.

9. A digital liability management and brand protection method, comprising:
intercepting internal network traffic and outgoing network traffic;
rerouting the intercepted network traffic to a traffic rule engine;
inspecting the rerouted traffic using preset rules to determine a part of the rerouted traffic to be analyzed;
extracting, using a particular protocol, the determined part of the rerouted traffic to be analyzed from the network traffic and reconstructing the outgoing message;
identifying suspect files transiting on the network by comparing the extracted traffic with one or more search packs to determine if a suspect file is transiting on the network, wherein said one or more search packs comprise a header, a search markup language program, and a protected asset data features section; and
outputting a report including a global map showing the locations of protected assets.

10. The digital liability and brand protection management method of claim 9, in which the header contains internal company contact information.

11. The digital liability and brand protection management method of claim 9, further comprising:
sharing said suspect files among a first entity and at least a second entity in a manner that enables utilization of the suspect data by the second entity while not revealing the actual content of sensitive data to the second entity.

12. The digital liability and brand protection management method of claim 9, wherein the preset rules can restrict the analysis to data coming from a local area network or going to a specific destination.

13. The digital liability and brand protection management method of claim 9, wherein the particular protocol is a communication protocol.

14. The digital liability and brand protection management method of claim 13, wherein the communication protocol is selected from the following: SMTP, SIP, NFS, Samba, FTP, HTTP, Jabber, and Gnutella.

15. The digital liability and brand protection management method of claim 9, wherein the one or more search packs identify protected assets.

16. A digital liability and brand protection management system, comprising:
a plurality of analysis modules and a traffic rule engine, wherein the traffic rule engine is coupled to said plurality of analysis modules and comprises preset rules, the traffic rule engine being configured to select, based on said preset rules, an incoming data packet for liability analysis by at least one of the plurality of analysis modules;
wherein each said analysis module is configured to extract information from said incoming data packet in accordance with one of a plurality of protocols; and
an identification module including one or more identification components comprising a header, a search markup language program, and a protected asset data features section, wherein the identification components are configured to identify suspect data and to allow sharing of said suspect data among a first entity and at least a second entity in a manner that enables utilization of the suspect data by the second entity while not revealing the actual content of sensitive data to the second entity;
wherein said identification module is configured to output a report including a global map showing the locations of protected assets.

17. The digital liability and brand protection management system of claim 16, wherein the suspect data is protected assets data.

18. The digital liability and brand protection management system of claim 16, wherein the features of data cannot be directly modified by the second entity.

19. The digital liability and brand protection management system of claim 16, wherein the one or more identification components identify protected assets.
